(19) United States
(12) Patent Application Publication
(10) Pub. No.: US 2005/0126696 A1
(43) Pub. Date: Jun. 16, 2005

(54) Snap cure device for semiconductor chip attachment

(76) Inventors: Kook-Jin Oh, Cheonan-si (KR); Young-Han Kwon, Cheonan-si (KR); Tae-Hyuk Kim, Cheonan-si (KR); Suk-Chun Jung, Cheonan-si (KR); Byung-Soo Kim, Cheonan-si (KR); Sang-Woo Lee, Cheonan-si (KR); Jung-Hyon Byon, Cheonan-si (KR)

Correspondence Address: HARNESS, DICKEY & PIERCE, P.L.C., P.O. BOX 8910, RESTON, VA, 20195, US

(21) Appl. No.: 10/976,790

(22) Filed: Nov. 1, 2004

(30) Foreign Application Priority Data
Dec. 11, 2003 (KR) 2003-90096

(51) Int. Cl. B32B 31/00; H01L 21/30; H01L 21/46

(52) U.S. Cl. 156/275.5; 438/455

(57) ABSTRACT

Provided are a variety of snap cure apparatus configuration and corresponding methods for operating each such apparatus in order to snap cure an adhesive composition. Each of the configurations includes at least one vertical stack of heater blocks whereby the horizontal area required for conducting the snap cure processing may be reduced. Depending on the configuration utilized, two or more transfer devices may be required to remove the substrate(s) from a conveyor, index the substrate(s) through the heater blocks to apply the predetermined thermal cycle and return the cured substrate to the conveyor. Similarly, depending on the particular adhesive utilized, the number, relative temperatures, and duration of the substrate(s) on each of the heater blocks may be adjusted to provide the desired degree of curing.

### CROSS REFERENCE TO RELATED APPLICATION

This U.S. non-provisional application claims priority under 35 U.S.C § 119 from Korean Patent Application No. 2003-90096 which was filed on Dec. 11, 2003, the entire contents of which are incorporated herein by reference.

### BACKGROUND OF THE INVENTION

1. Field of the Invention

The present invention relates to an apparatus and a method for attaching semiconductor chips to substrates and, more particularly, to an apparatus and a method for operating the apparatus for performing a snap cure process during the attachment of a semiconductor chip to a substrate.

2. Description of the Related Art

The chip attaching process of a semiconductor package manufacturing process typically separates semiconductor chips from a wafer and then attaches the semiconductor chips to a substrate using an adhesive. The adhesive may include an adhesive tape and/or a liquid adhesive and typically requires a curing after the semiconductor chip process has been attached. The curing processes may include an oven cure and/or a snap cure depending on the characteristics and performance of the adhesive(s) used in the semiconductor chip attachment.

A snap cure device used in the snap cure process may be arranged inline with the semiconductor chip attaching apparatus, examples of which are disclosed in Japanese Publication Nos. 05-226390 and 07-106348. The conventional snap cure device may occupy a considerable space due to the horizontal arrangement of the plurality of curing zones.

In order to reduce the space required, Japanese Publication No. 10-163234 discloses a curing device in which a plurality of curing zones are arranged perpendicularly to the direction of transfer of the substrate. However, this curing device may also utilize a horizontal arrangement of the curing zones and therefore limit the degree of reduction that can be achieved in the area occupied by the snap cure device.

### SUMMARY OF THE INVENTION

An exemplary snap cure device is provided in which at least one curing zone is arranged vertically. The snap cure device comprises a substrate conveyor for conveying substrates with a plurality of heater blocks installed above the substrate conveyor and arranged vertically at predetermined intervals. A transfer means may be utilized to transfer the substrates between the substrate conveyor and the heater blocks.

In accordance with an exemplary embodiment of the apparatus, eight heater blocks are arranged in a Z-axis direction and associated with a transfer means that includes a first fork and a second fork. The first fork transfers the substrates from the substrate conveyor to the heater blocks while the second fork transfers the substrates from the heater block to the substrate conveyor.

In accordance with another exemplary embodiment, the heater blocks may be arranged in two adjacent rows that are aligned in an X-axis direction. In the particular arrangement illustrated, the heater blocks include a first heater block row and a second heater block row with the first heater block row located above the substrate conveyor and the second heater block row also located above the substrate conveyor and adjacent the first heater block row in the direction of travel of the substrate conveyor. The first and second heater block rows each have four heater blocks and are associated with a transfer means that comprises a first fork, a second fork and a third fork. The first fork transfers the substrates from the substrate conveyor to the heater blocks in the first heater block row, the second fork transfers the substrates from the uppermost heater block in the first heater block row to the corresponding uppermost heater block in the second heater block row. The third fork is then used to transfer the substrates through the second heater block row and from the second heater block row to the substrate conveyor.

In accordance with yet another exemplary embodiment, the heater blocks may be arranged in two rows generally aligned along the Y-axis. The heater blocks include a first heater block row and a second heater block row with the first heater block row located above the substrate conveyor, and the second heater block row spaced apart from the substrate conveyor in the Y-axis direction and substantially parallel to the first heater block row. A dummy substrate conveyor may be installed below the second heater block row and substantially parallel to the substrate conveyor. The first and second heater block rows can each have four heater blocks that are associated with a transfer means that comprises a first fork, a second fork, a third fork and a fourth fork. The first fork transfers the substrates from the substrate conveyor to the heater blocks of the first heater block row and the second fork transfers the substrates from the uppermost heater block of the first heater block row to the corresponding uppermost heater block of the second heater block row. The third fork transfers the substrates from the second heater block row to the dummy substrate conveyor while the fourth fork transfers the substrates from the dummy substrate conveyor to the substrate conveyor.

### BRIEF DESCRIPTION OF THE DRAWINGS

Exemplary embodiments of the present invention will be described with reference to the accompanying drawings in which identical reference numerals designate similar or corresponding structural elements, and, in which:

FIG. 1 is a schematic block diagram illustrating a snap cure device in accordance with an exemplary embodiment of the present invention;

FIG. 2 is a plane view of FIG. 1;

FIG. 3 is a cross-sectional view taken along a line of 3-3 of FIG. 2;

FIG. 4 is a view illustrating the step of transferring substrates in accordance with an exemplary embodiment of the present invention;

FIG. 5 is a plane view illustrating a snap cure device in accordance with another exemplary embodiment of the present invention;

FIG. 6 is a view illustrating the step of transferring the substrates of the snap cure device of FIG. 5;

FIG. 7 is a plane view illustrating a snap cure device in accordance with yet another exemplary embodiment of the present invention; and

FIG. 8 is a view illustrating the step of transferring the substrates of the snap cure device of FIG. 7.

### DETAILED DESCRIPTION OF THE EXEMPLARY EMBODIMENTS

Exemplary embodiments of the present invention will be described below with reference to the accompanying drawings. It will be understood that the depicted elements may be enlarged, reduced, simplified and/or merely exemplary, and may not necessarily be drawn to scale.

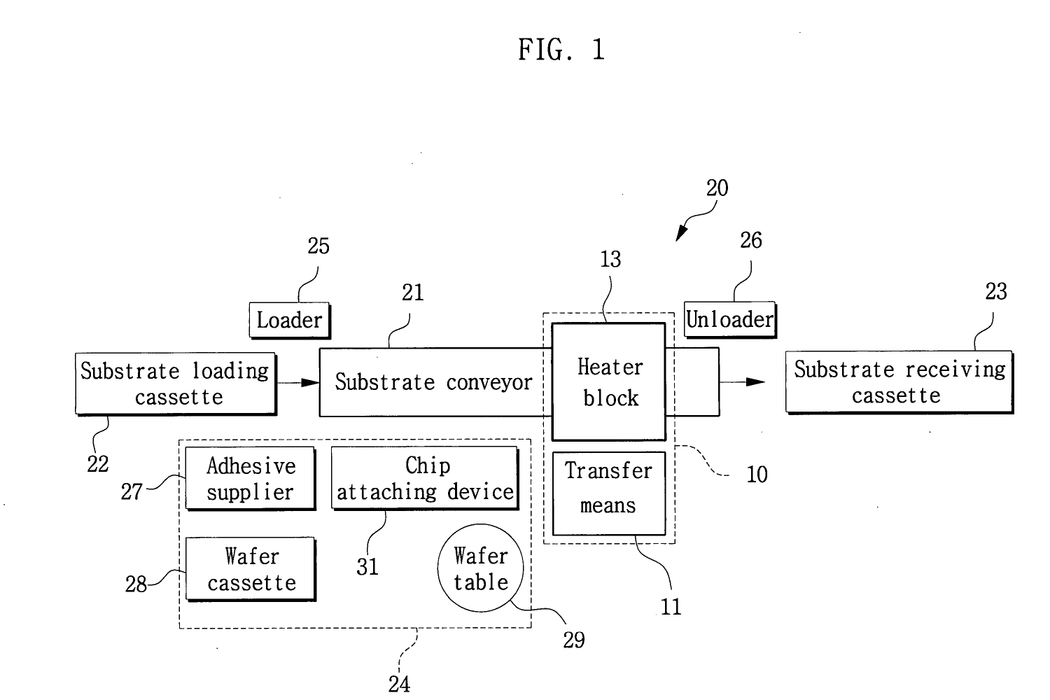

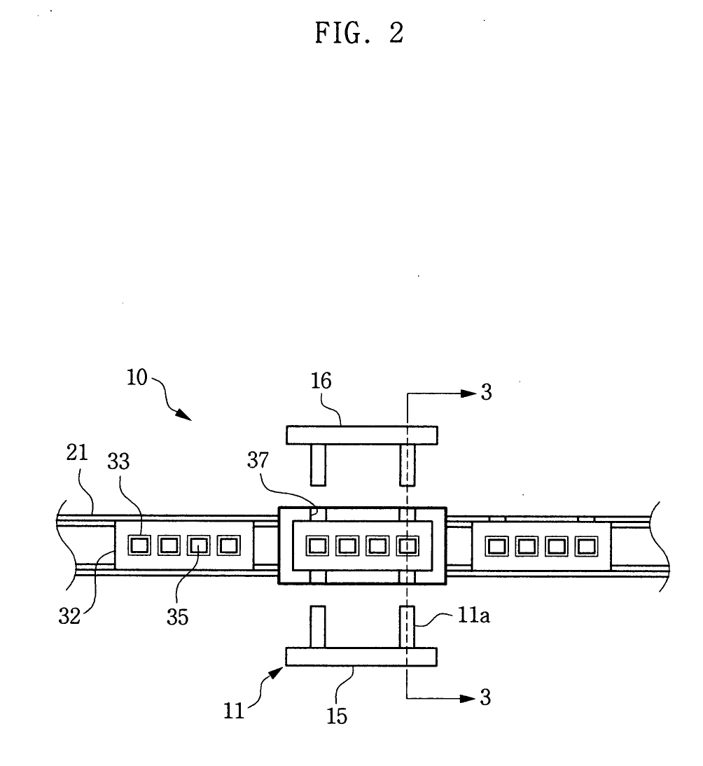

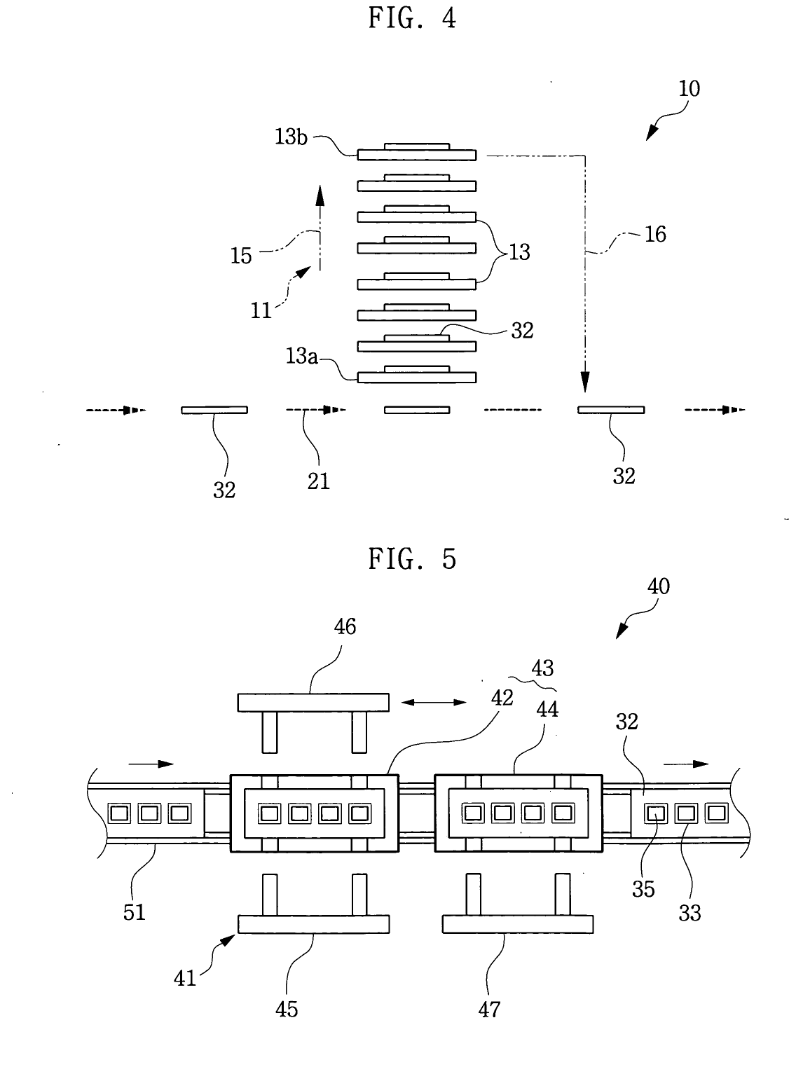

FIG. 1 is a schematic block diagram of a semiconductor chip attaching apparatus 20 in accordance with an exemplary embodiment of the present invention, in which a snap cure device 10 is installed above a substrate conveyor 21. FIG. 4 illustrates the step of transferring substrates 32 in the snap cure device 10 of FIG. 2. For the purposes of the following discussion the longitudinal axis and the conveying direction of the substrate conveyor 21 will be referred to as the X-axis with the Y-axis being perpendicular to the X-axis and generally parallel to the main surface of the substrate conveyor and the Z-axis being perpendicular to both the X-axis and the Y-axis.

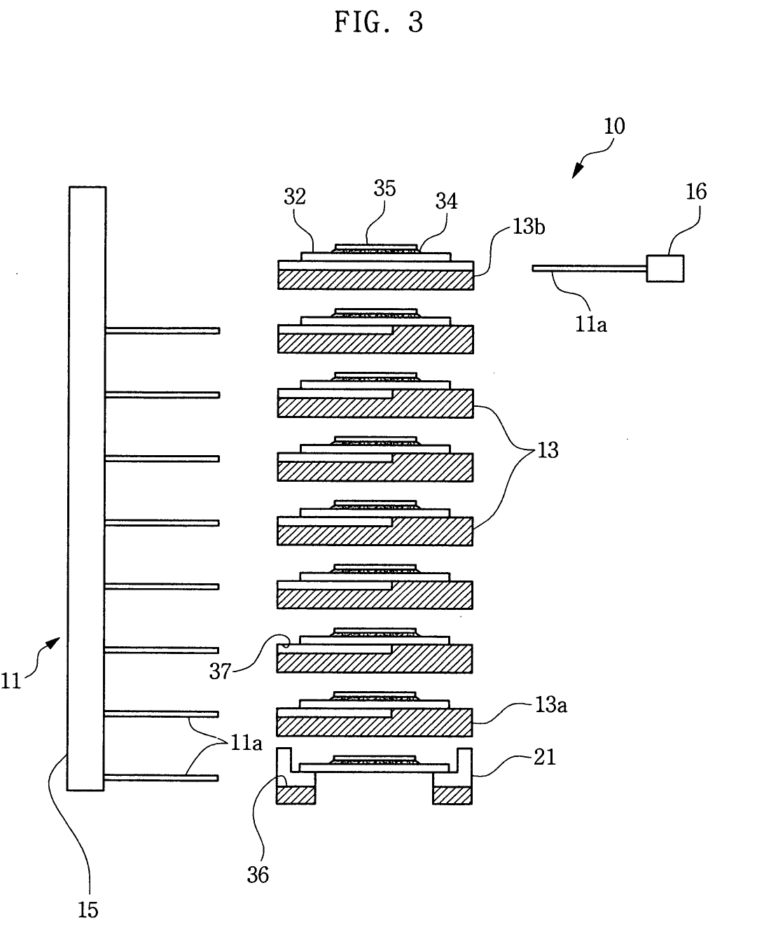

As illustrated in FIGS. 1-4, the semiconductor chip attaching apparatus 20 comprises a chip attaching unit 24 and a snap cure device 10. The chip attaching unit 24 applies an adhesive 34 to a substrate 32 and attaches a semiconductor chip 35 to the substrate 32. The snap cure device 10 then performs a snap cure process on the substrates 32 having the semiconductor chip 35. In this embodiment, the snap cure device 10 is installed above the substrate conveyor 21. Alternatively, the snap cure device 10 may be installed inline with a conventional semiconductor chip attaching apparatus.

As illustrated the semiconductor chip attaching apparatus 20 typically includes a substrate loading cassette 22 located at one end of the substrate conveyor 21 and a substrate receiving cassette 23 located at the other end of the substrate conveyor 21. The substrate loading cassette 22 loads the substrates 32 before a chip attaching process. The substrate receiving cassette 23 receives the substrates 32 on which the semiconductor chips 35 have been mounted after the snap cure process. The substrate 32 may be a lead frame strip, a printed circuit board, a tape wiring substrate or other structure designed and configured to receive and mount one or more semiconductor chips. In case of a lead frame strip, the substrate loading cassette 22 may be a magazine from which the substrates 32 are placed one at a time on to the substrate conveyor 21 by a loader 25.

The substrate 32 includes at least one chip attaching area 33 to which the semiconductor chip 35 may be attached. The substrate conveyor 21 may convey the substrates 32 at a predetermined interval or rate during the chip attaching and snap cure processes sufficient to support a consecutive and substantially continuous operation. The substrate conveyor 21 may employ a conventional member transfer system such as a transfer rail. The substrate conveyor 21 is installed longitudinally below the substrate 32. After the snap cure process has been completed, the substrates 32 may be transferred from the substrate conveyor 21 to the substrate receiving cassette 23 by an unloader 26.

The chip attaching unit 24 comprises an adhesive supplier 27, a wafer cassette 28, a wafer table 29 and a chip attaching device 31. The adhesive supplier 27 supplies the adhesive 34 to the substrate 32. The wafer table 29 supports and typically orients the wafers from which the semiconductor chips 35 will be separated. The chip attaching device 31 is installed between the wafer table 29 and the substrate conveyor 21 and separates the semiconductor chip 35 from the wafer and attaches the semiconductor chip 35 to the adhesive 34 applied on the substrate 32. The wafer is transferred from the wafer cassette 28 to the wafer table 29.

The adhesive supplier 27 supplies the adhesive 34 to the chip attaching area 33 of the substrate 32 as the substrates are conveyed past the chip attaching unit 24. The adhesive 34 may be a double-sided adhesive tape or a liquid adhesive. The double-sided adhesive tape may be a polyimide tape while the liquid adhesive may be a conductive liquid adhesive such as Ag-epoxy, Ag-glass or solder, or may be a non-conductive liquid adhesive such as silicone.

The chip attaching device 31 attaches the semiconductor chip 35 to the chip attaching area 33 of the substrate 32. The semiconductor chip 35 is typically provided from a wafer including a plurality of individual semiconductor chips 35 provided on the wafer table 29. The chip attaching device 31 is located between the wafer table 29 and the substrate conveyor 21 and reciprocates therebetween. The chip attaching device 31 absorbs the semiconductor chip 35, typically by vacuum, in order to separate it from the wafer and then places and presses the semiconductor chip 35 onto the substrate 32. The attachment of the semiconductor chip 35 typically includes application of both heat and pressure.

The snap cure device 10 is installed near the substrate conveyor 21 adjacent the chip attaching unit 24. The snap cure device 10 cures the adhesive 34 using a plurality of heater blocks 13 arranged in the direction of the Z-axis. The snap cure device 10 performs a snap cure process gradually on the substrate 32 by moving the substrates 32 progressively through each of the heater blocks 13 in the direction of the Z-axis.

The snap cure device 10 comprises the heater blocks 13 and a transfer means 11. The heater blocks 13 are each spaced at predetermined intervals. The transfer means 11 transfers the substrate 32 between the substrate conveyor 21 and the heater blocks 13.

The first exemplary embodiment is illustrated with eight heater blocks 13 installed above the substrate conveyor 21 in the direction of the Z-axis as shown in FIGS. 2 through 4. The transfer means 11 comprises a first fork 15 and a second fork 16. Although illustrated and described herein as “forks,” those of ordinary skill will appreciate that a variety of transfer devices may be used including, for example, vacuum assisted devices, devices having one or more than two contact bars and devices including additional mechanisms for gripping or holding the substrate during transfer operations. The first fork 15 transfers the substrate 32 from the substrate conveyor 21 to the first or lowest heater block 13a through intermediate heater blocks 13, and to the last or uppermost heater block 13b. The second fork 16 transfers the cured substrate 32 from the uppermost heater block 13b to the substrate conveyor 21. As illustrated, the first and second forks 15 and 16 may be installed on opposite sides of the substrate conveyor 21. Alternatively, the first and second forks 15 and 16 may be both installed on the same side of the substrate conveyor 21.

The first fork 15 and the second fork 16 include transfer bars 11a for loading/unloading the substrates 32. The transfer bars 11a of the first fork 15 are spaced at predetermined intervals corresponding to the spacing of the heater blocks 13. The substrate conveyor 21 and the heater blocks 13 have grooves 36 and 37 respectively for inserting the transfer bars 11a below the substrates 32. The first fork 15 is movable to transfer the substrates 32 from the substrate conveyor 21 to the first heater block 13 and successively through the intermediate heater blocks 13 in the direction of the Z-axis. The second fork 16 is movable to transfer the substrate 32 from the uppermost heater block 13b downward onto the substrate conveyor 21. The number of transfer bars 11a provided on the first fork 15 may be the same as the number of heater blocks 13 or may be less than the number of heater blocks.

The snap cure process may be performed using a temperature range of 100° C. to 220° C. and may have a duration of between 1 and 5 minutes. The snap cure process proceeds by gradually increasing and decreasing the temperature of the heater blocks 13. In this embodiment, the temperature of the heater blocks 13 may be set at 100° C., 150° C., 180° C., 220° C., 220° C., 180° C., 150° C., 100° C. from lowest to uppermost to provide a thermal cycle including ramp-up, cure and ramp down periods. As will be appreciated by those of ordinary skill in the art, the number and relative temperatures of the heater blocks may be adapted as necessary for the particular devices, substrates and adhesives being utilized. The substrates 32 remain on each of the heater blocks 13 for the same period of time and may be moved or indexed simultaneously, thus avoiding mechanical interference that may otherwise occur when transferring the substrates 32.

In accordance with the first exemplary embodiment, the snap cure device 10 includes heater blocks 13 installed in the direction of the Z-axis, thereby reducing the horizontal area occupied by the snap cure device 10 within the chip attaching apparatus (20 of FIG. 1). The snap cure device 10 may be located above the substrate conveyor 21 near the substrate receiving cassette 23. As will be appreciated, the snap cure device 10 may also be provided separately from the semiconductor chip attaching apparatus (20 of FIG. 1) by, for example being incorporated in a separate downstream unit that can be installed inline with the output of the substrate conveyor 21 and may include a separate substrate conveyor (not shown) or to which attached, but uncured, substrates are transferred by another means.

In another exemplary embodiment, the snap cure device may include heater blocks arranged in a plurality of rows to reduce the vertical space requirements while still reducing the horizontal area required. Such arrangements typically will adopt an X-axis expansion and/or Y-axis expansion configurations.

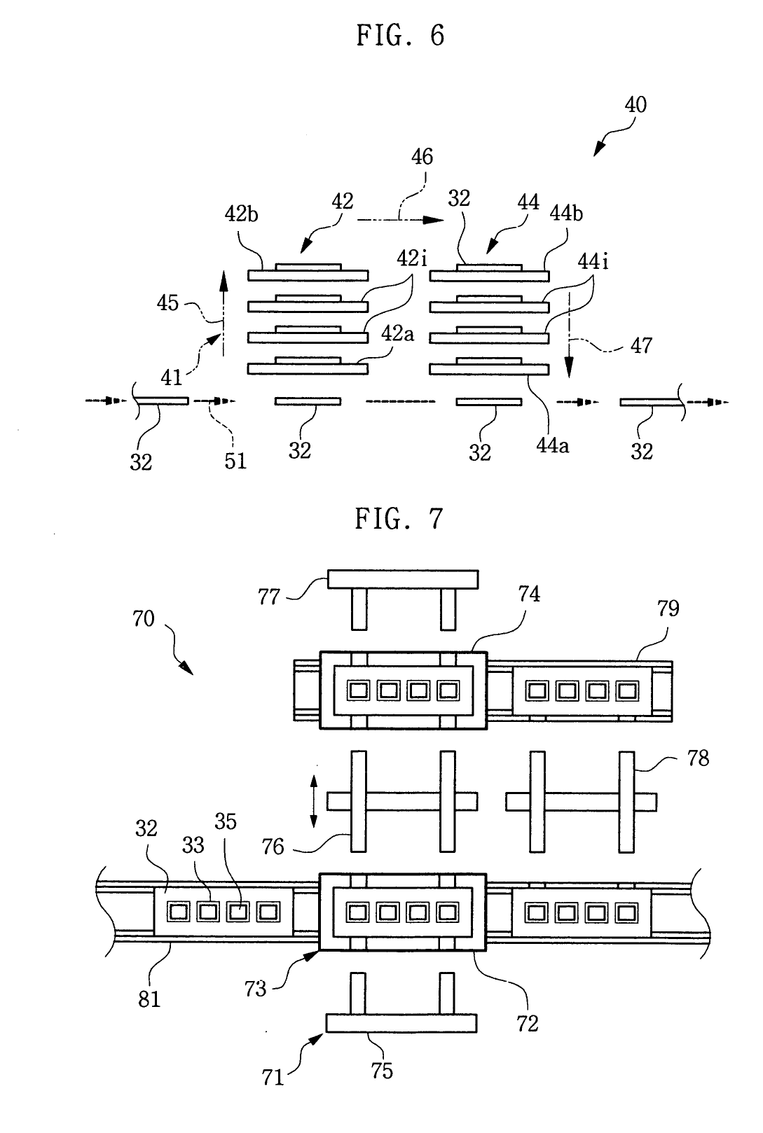

The second exemplary embodiment illustrates an X-axis expansion type snap cure device 40. Heater blocks 43 include a first heater block row 42 and a second heater block row 44, as shown in FIGS. 5 and 6. The first heater block row 42 is located above a substrate conveyor 51. The second heater block row 44 is located adjacent to the first heater block row 42 in the direction of travel of the substrate conveyor 51 (i.e., the X-axis direction).

A transfer means 41 includes a first fork 45, a second fork 46 and a third fork 47. The first fork 45 transfers the substrates 32 from the substrate conveyor 51 to the heater blocks of the first heater block row 42 in the direction of the Z-axis, i.e. from the first or lowest heater block 42a to the last or uppermost heater block 42b. The second fork 46 transfers the substrates 32 from the uppermost heater block 42b of the first heater block row 42 to the corresponding uppermost heater block 44b of the second heater block row 44. The third fork 47 transfers the substrates 32 from the uppermost heater block 44b, through the intermediate heater blocks 441, and to the lowest heater block 44a of the second heater block row 44 in the direction of the Z-axis and then to the substrate conveyor 51.

Therefore, the substrates 32 from the substrate conveyor 51 are transferred upwardly through heater block row 42 in the direction of the Z-axis by the first fork 45, in the direction of the X-axis by the second fork 46 and then downwardly through heater row 44 in the direction of the Z-axis by the third fork 47 and returned to the substrate conveyor 51. The number of transfer bars provided on the first and third forks 45 and 47 will typically correspond to the number of heater blocks in the respective heater block rows 42 and 44. Similarly, the first fork 45 and the second fork 46 will typically be installed on opposite sides of the substrate conveyor 21 with the third fork 47 installed adjacent to the first fork 45 and offset in the “downstream” or X-axis direction.

The second exemplary embodiment is similar to the first exemplary embodiment in that the snap cure process is performed gradually through eight heater blocks, except for the direction of transfer through the heater blocks. The heater blocks 43 may be set at the same temperatures as suggested for the first exemplary embodiment and the first and third forks 45 and 47 may each have four transfer bars.

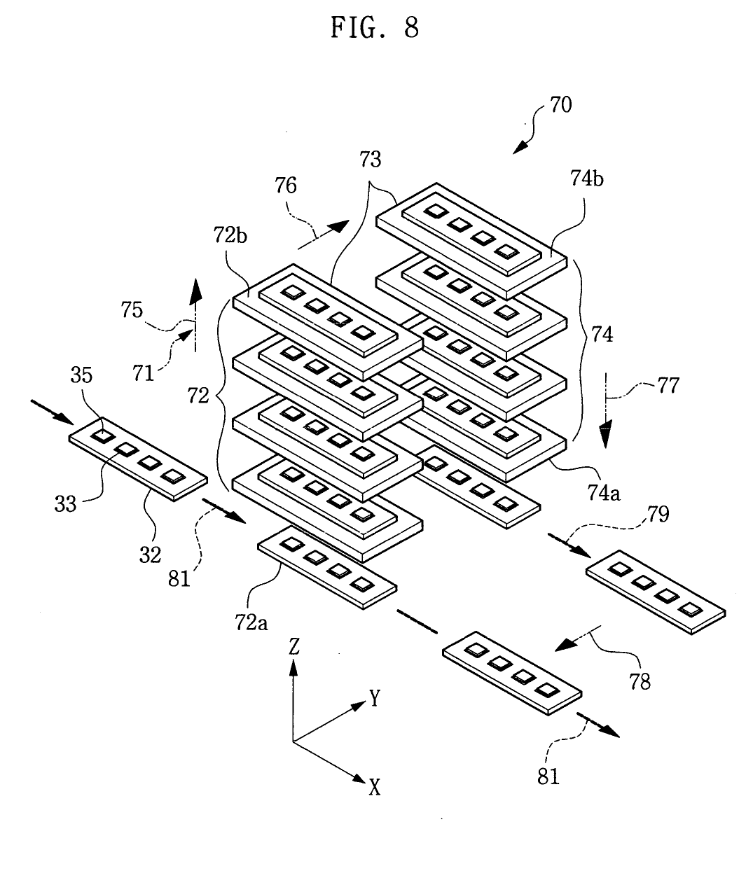

The third exemplary embodiment illustrates a Y-axis expansion type snap cure device 70. Heater blocks 73 may be arranged in a first heater block row 72 and a second heater block row 74 as illustrated in FIGS. 7 and 8. The first heater block row 72 is located above a substrate conveyor 81. The second heater block row 74 is spaced or offset a predetermined distance from the substrate conveyor 81 along the Y-axis and substantially parallel to the first heater block row 72. A dummy substrate conveyor 79 may be installed parallel to the substrate conveyor 81 and adjacent the second heater block row 74.

A transfer means 71 includes a first fork 75, a second fork 76, a third fork 77 and a fourth fork 78. The first fork 75 transfers the substrates 32 from the substrate conveyor 81 to the heater blocks of the first heater block row 72 in the direction of the Z-axis, i.e. from the first or lowest heater block 72a to the last or uppermost heater block 72b. The second fork 76 transfers the substrates 32 from the uppermost heater block 72b of the first heater block row 72 to the corresponding uppermost heater block 74b of the second heater block row 74. The third fork 77 then transfers the substrates 32 from the uppermost heater block 74b to the lowest heater block 74a of the second heater block row 74 in the direction of the Z-axis and on to the dummy substrate conveyor 79. The fourth fork 78 transfers the substrates 32 from the dummy substrate conveyor 79 to the adjacent substrate conveyor 81. Therefore, the substrates 32 from the substrate conveyor 81 are transferred in the Z-axis direction by the first fork 75, in the Y-axis direction by the second fork 76, in the Z-axis direction by the third fork 77 and then in the Y-axis direction by the fourth fork 78 and returned to the substrate conveyor 81. The number of transfer bars provided on the first and third forks 75 and 77 will typically correspond to the number of heater blocks included in each of the heater block rows 72 and 74, respectively. The second and fourth forks 72 and 74 will typically be installed between the substrate conveyor 81 and the dummy substrate conveyor 79. As illustrated in FIG. 7, the first fork 75 and the second fork 76 will typically be installed on opposite sides of the substrate conveyor 81 with the second fork 76 and the third fork 77 being installed on opposite sides of the dummy substrate conveyor 79.

The third exemplary embodiment is similar to the first and second exemplary embodiments in that the snap cure process is performed gradually using eight heater blocks, but utilizes a different transfer sequence as a result of the altered configuration of the heater blocks. The heater blocks 73, 74 may be set at the same temperatures as corresponding heater blocks in the first embodiment and the first and third forks 75 and 77 can each have four transfer bars.

Accordingly, the present invention may allow for the vertical and/or horizontal rearrangement of heater blocks to reduce the horizontal area occupied by a snap cure device utilized in a semiconductor chip attaching apparatus. The snap cure device may be incorporated within or arranged inline with a substrate conveyor of a conventional chip attaching apparatus.

Although certain exemplary embodiments of the present invention have been described in detail, it should be understood that many variations and/or modifications of the basic inventive concepts may appear to those skilled in the art when instructed by this disclosure and will still fall within the spirit and scope of the present invention as defined in the following claims.

1. A snap cure apparatus arranged adjacent a substrate conveyor, the snap cure apparatus comprising:
a plurality of heater blocks arranged in a vertically stacked configuration;
a first transfer device for moving a substrate from the substrate conveyor onto a first heater block; and
a second transfer device for moving the substrate from a last heater block to the substrate conveyor.

2. A snap cure apparatus according to claim 1, wherein:
the first transfer device is arranged and configured to move the substrate from the first heater block to an intermediate heater block.

3. A snap cure apparatus according to claim 1, wherein:
the second transfer device is arranged and configured to move the substrate from an intermediate heater block to the last heater block.

4. A snap cure apparatus according to claim 1, wherein:
the first transfer device is arranged and configured to move the substrate from the first heater block to an intermediate heater block and from the intermediate heater block to the last heater block.

5. A snap cure apparatus according to claim 1, wherein:
the second transfer device is arranged and configured to move the substrate from the first heater block to an intermediate heater block and from the intermediate heater block to the last heater block.

6. A snap cure apparatus according to claim 1, further comprising:
a third transfer device is arranged and configured to move the substrate from a first group of heater blocks to a second group of heater blocks.

7. A snap cure apparatus according to claim 6, wherein:
the first group of heater blocks is positioned generally above the substrate conveyor and the second group of heater blocks is offset from the first group of heater blocks in a direction generally perpendicular to a main axis of the substrate conveyor.

8. A snap cure apparatus according to claim 1, wherein:
the first group of heater blocks is positioned generally above the substrate conveyor; and
the second group of heater blocks is positioned generally above the substrate conveyor and offset from the first group of heater blocks in a downstream direction.

9. A snap cure apparatus according to claim 2, wherein:
the first transfer device is arranged and configured to move a first substrate from the first heater block to the intermediate heater block and to move a second substrate from the substrate conveyor to the first heater block, whereby the first substrate and the second substrate are moved simultaneously.

10. A snap cure apparatus according to claim 3, wherein:
the second transfer device is arranged and configured to move a first substrate from the last heater block to the substrate conveyor and to move a second substrate from the intermediate heater block to the last heater block, whereby the first substrate and the second substrate are moved simultaneously.

11. A snap cure apparatus according to claim 1, wherein:
each of the heater blocks is spaced from each vertically adjacent heater block by a predetermined separation distance.

12. A snap cure apparatus according to claim 11, wherein:
the first heater block is separated from the substrate conveyor by the predetermined separation distance.

13. A snap cure apparatus according to claim 11, wherein:
the last heater block is separated from the substrate conveyor by the predetermined separation distance.

14. A snap cure apparatus arranged adjacent a substrate conveyor, the snap cure apparatus comprising:
a first group of heater blocks arranged in a vertically stacked configuration;
a first transfer device arranged and configured to move the substrate from the substrate conveyor to a first heater block in the first group of heater blocks;
a second group of heater blocks arranged in a vertically stacked configuration;
a second transfer device arranged and configured to move the substrate from an intermediate heater block in the first group to an intermediate heater block in the second group;
a second substrate conveyor; and
a third transfer device arranged and configured to move the substrate from a last heater block in the second group to the second substrate conveyor.

15. A snap cure apparatus according to claim 14, further comprising:
a fourth transfer device arranged and configured to move the substrate from the second substrate conveyor the substrate conveyor.

16. A snap cure apparatus according to claim 14, wherein:
the first transfer device is arranged and configured to move the substrate from the first heater block to an intermediate heater block; and
the third transfer device is arranged and configured to move the substrate from the intermediate heater block to the last heater block.

17. A method of snap curing an adhesive provided on a substrate comprising:
removing the substrate including an uncured adhesive from a substrate conveyor;
placing the substrate on a first heater block, the first heater block being maintained at a first temperature T₁;
moving the substrate to a first intermediate heater block, the first intermediate heater block being arranged in a vertically stacked relationship with the first heater block and being maintained at a second temperature T₂, wherein T₂>T₁;
moving the substrate to a last intermediate heater block, the second intermediate heater block being maintained at a third temperature T₃;
moving the substrate to a last heater block, the last heater block being arranged in a vertically stacked relationship with the last intermediate heater block and being maintained at a fourth temperature T₄, wherein T₃>T₄; and
returning the substrate with a snap cured adhesive to the substrate conveyor.

18. A method of snap curing an adhesive according to claim 17, wherein the adhesive is provided on a plurality of substrates, further comprising:
moving a first substrate from the last heater block to the substrate conveyor;
moving a second substrate from the last intermediate heater block to the last heater block;
moving a third substrate from the first heater block to the first intermediate heater block; and
moving a fourth substrate from the substrate conveyor to the first heater block, wherein the steps of moving the first, second, third and fourth substrates occurs substantially simultaneously.

19. A method of snap curing an adhesive according to claim 18, further comprising:
indexing an additional N substrates through an additional N intermediate heater blocks, the additional intermediate heater blocks being arranged between the first intermediate and the last intermediate heater blocks.

20. A method of snap curing an adhesive according to claim 19, further comprising:
maintaining the additional N intermediate heater blocks at predetermined temperatures whereby a substrate moving from the first heater block, through the intermediate heater blocks and to the last heater block is heated and then cooled before being returned to the substrate conveyor.
